(19) United States
(12) Patent Application Publication
(10) Pub. No.: US 2025/0096533 A1
(43) Pub. Date: Mar. 20, 2025

(54) OPTICAL SEMICONDUCTOR ELEMENT

(71) Applicants: SUMITOMO ELECTRIC INDUSTRIES, LTD., Osaka (JP); SUMITOMO ELECTRIC DEVICE INNOVATIONS, INC., Yokohama-shi (JP)

(72) Inventors: Daisuke Inoue, Osaka-shi (JP); Konosuke Aoyama, Yokohama-shi (JP)

(73) Assignees: SUMITOMO ELECTRIC INDUSTRIES, LTD., Osaka (JP); SUMITOMO ELECTRIC DEVICE INNOVATIONS, INC., Yokohama-shi (JP)

(21) Appl. No.: 18/829,660

(22) Filed: Sep. 10, 2024

(30) Foreign Application Priority Data
Sep. 20, 2023 (JP) 2023-152189

(51) Int. Cl. H01S 5/22; H01S 5/02; H01S 5/026; H01S 5/042; H01S 5/12; H01S 5/227

(52) U.S. Cl. CPC H01S 5/2201; H01S 5/0206; H01S 5/026; H01S 5/04256; H01S 5/227; H01S 5/12

(57) ABSTRACT

An optical semiconductor element includes a substrate having a first main surface whose plane orientation is {100} and a second main surface provided opposite to the first main surface, and a first semiconductor layer provided on the first main surface and provided with a mesa. The mesa includes a laser portion and an optical amplifier portion. The laser portion includes a first surface perpendicular to the first main surface, and a second surface perpendicular to the first main surface and parallel to the first surface. The optical amplifier portion includes a third surface perpendicular to the first main surface and contiguous with the first surface, a fourth surface perpendicular to the first main surface and contiguous with the second surface, a fifth surface perpendicular to the first main surface and contiguous with the third surface.

### CROSS REFERENCE TO RELATED APPLICATIONS

This application claims priority based on Japanese Patent Application No. 2023-152189 filed on Sep. 20, 2023, and the entire contents of the Japanese patent application are incorporated herein by reference.

### TECHNICAL FIELD

The present disclosure relates to an optical semiconductor element.

### BACKGROUND

An optical semiconductor element in which a distributed feedback (DFB) laser and a semiconductor optical amplifier (SOA) are integrated is known.

Further, an optical semiconductor element in which the optical axis is shifted between the DFB laser and the SOA is also known.
Patent literature 1: U.S. Patent Application Publication No. 2012-0243074

### NON PATENT LITERATURE

Non-patent literature 1: M. Faugeron et al., “High power three-section integrated master oscillator power amplifier at 1.5 μm”, IEEE Photon. Technol. Lett., vol. 27, no. 13, pp. 1449-1452, July 2015

### SUMMARY

An optical semiconductor element includes a substrate having a first main surface whose plane orientation is {100} and a second main surface provided opposite to the first main surface, and a first semiconductor layer provided on the first main surface and provided with a mesa. The mesa includes a laser portion and an optical amplifier portion. The laser portion includes a first surface perpendicular to the first main surface, and a second surface perpendicular to the first main surface and parallel to the first surface. The optical amplifier portion includes a third surface perpendicular to the first main surface and contiguous with the first surface, a fourth surface perpendicular to the first main surface and contiguous with the second surface, a fifth surface perpendicular to the first main surface and contiguous with the third surface, a sixth surface perpendicular to the first main surface, contiguous with the fourth surface, and parallel to the fifth surface, and an end surface perpendicular to the first main surface, contiguous with the fifth surface and the sixth surface, and from which light is emitted. A first distance between the first surface and the second surface is smaller than a second distance between the fifth surface and the sixth surface. The first surface and the second surface are parallel to a {01-1} plane of the substrate. The end surface is perpendicular to the {01-1} plane. The third surface and the fourth surface are inclined in a same direction with respect to each other from the {01-1} plane in a plane parallel to the first main surface. The third surface is inclined more from the {01-1} plane than the fourth surface in the plane parallel to the first main surface. The fifth surface and the sixth surface are inclined in a same direction as the third surface and the fourth surface from the {01-1} plane in the plane parallel to the first main surface. The optical semiconductor element includes a second semiconductor layer contacting the first surface, the second surface, the third surface, the fourth surface, the fifth surface, and the sixth surface, a first electrode pad provided at a position where the laser portion is interposed between the substrate and the first electrode pad, including a first metal, and electrically connected to the laser portion, a second electrode pad provided at a position where the optical amplifier portion is interposed between the substrate and the second electrode pad, including a second metal, and electrically connected to the optical amplifier portion, and a third electrode pad provided at the second main surface, electrically connected to the substrate, and including a third metal. In plan view, on an outer side of the first electrode pad, the optical semiconductor element includes a first region situated on an extension line of the laser portion on a propagation direction side of light propagating in a straight line inside the laser portion, and a second region overlapping the optical amplifier portion. A ratio of a metal film covering the first semiconductor layer or the second semiconductor layer is lower inside the first region than inside the second region.

### BRIEF DESCRIPTION OF THE DRAWINGS

FIG. 1 is a plan view showing an optical semiconductor element according to a first embodiment.

FIG. 2 is a plan view showing a configuration of a first semiconductor layer in a first embodiment.

FIG. 3 is a cross-sectional view (part 1) showing an optical semiconductor element according to a first embodiment.

FIG. 4 is a cross-sectional view (part 2) showing an optical semiconductor element according to the first embodiment.

FIG. 5 is a cross-sectional view (part 3) showing an optical semiconductor element according to a first embodiment.

FIG. 6 is a cross-sectional view (part 4) showing an optical semiconductor element according to the first embodiment.

FIG. 7 is a cross-sectional view (part 1) showing a method of manufacturing an optical semiconductor element 1 according to the first embodiment.

FIG. 8 is a cross-sectional view (part 2) showing a manufacturing method of optical semiconductor element 1 according to the first embodiment.

FIG. 9 is a cross-sectional view (part 3) showing a manufacturing method of optical semiconductor element 1 according to the first embodiment.

FIG. 10 is a cross-sectional view (part 4) showing a manufacturing method of optical semiconductor element 1 according to the first embodiment.

FIG. 11 is a cross-sectional view (part 5) showing a manufacturing method of optical semiconductor element 1 according to the first embodiment.

FIG. 12 is a cross-sectional view (part 6) showing a manufacturing method of optical semiconductor element 1 according to the first embodiment.

FIG. 13 is a cross-sectional view (part 7) showing a manufacturing method of optical semiconductor element 1 according to the first embodiment.

FIG. 14 is a cross-sectional view (part 8) showing a manufacturing method of optical semiconductor element 1 according to the first embodiment.

FIG. 15 is a cross-sectional view (part 9) showing a manufacturing method of optical semiconductor element 1 according to the first embodiment.

FIG. 16 is a cross-sectional view (part 10) showing a manufacturing method of optical semiconductor element 1 according to the first embodiment.

FIG. 17 is a diagram showing a relationship between the inclination angle and the reflectance at the end surface.

FIG. 18 is a diagram showing a relationship between a radius of curvature in a tapered portion and a transmittance of light from a laser portion to an optical amplifier portion.

FIG. 19 is a plan view showing an optical semiconductor element according to a second embodiment.

FIG. 20 is a plan view showing an optical semiconductor element according to a third embodiment.

FIG. 21 is a plan view showing an optical semiconductor element according to a fourth embodiment.

FIG. 22 is a plan view showing an optical semiconductor element according to a fifth embodiment.

### DETAILED DESCRIPTION

In optical semiconductor devices where the optical axis is shifted between conventional DFB lasers and SOAs, it is not possible to accurately evaluate the characteristics of the optical semiconductor device due to the influence of radiated synchrotron radiation from the DFB laser outside the SOA. For example, even when the spread angle in the far-field pattern is to be evaluated, the far-field pattern is likely to include a vibration component, and the accuracy of the half-value width or the like is reduced. Thus, it is difficult to estimate the coupling efficiency with the optical fiber with high accuracy.

An object of the present disclosure is to provide an optical semiconductor element whose characteristics can be evaluated with high accuracy.

### Description of Embodiments of Present Disclosure

First, embodiments of the present disclosure will be listed and described. In the following description, the same or corresponding elements are denoted by the same reference signs, and the same description thereof will not be repeated. In the crystallographic descriptions in the present disclosure, an individual orientation is represented by [ ], a group orientation is represented by < >, an individual plane is represented by ( ), and a group plane is represented by { }. A negative crystallographic index is usually represented by “−” (a bar) above a numeral, but in the present disclosure, a negative sign is placed before a numeral. Further, when viewed from an arbitrary point, the [100] side of the substrate may be referred to as upward, upper side, or above, and the [−100] side of the substrate may be referred to as downward, lower side, or below.

[1] An optical semiconductor element according to an aspect of the present disclosure includes a substrate having a first main surface whose plane orientation is {100} and a second main surface provided opposite to the first main surface, and a first semiconductor layer provided on the first main surface and provided with a mesa. The mesa includes a laser portion and an optical amplifier portion. The laser portion includes a first surface perpendicular to the first main surface, and a second surface perpendicular to the first main surface and parallel to the first surface. The optical amplifier portion includes a third surface perpendicular to the first main surface and contiguous with the first surface, a fourth surface perpendicular to the first main surface and contiguous with the second surface, a fifth surface perpendicular to the first main surface and contiguous with the third surface, a sixth surface perpendicular to the first main surface, contiguous with the fourth surface, and parallel to the fifth surface, and an end surface perpendicular to the first main surface, contiguous with the fifth surface and the sixth surface, and from which light is emitted. A first distance between the first surface and the second surface is smaller than a second distance between the fifth surface and the sixth surface. The first surface and the second surface are parallel to a {01-1} plane of the substrate. The end surface is perpendicular to the {01-1} plane. The third surface and the fourth surface are inclined in a same direction with respect to each other from the {01-1} plane in a plane parallel to the first main surface. The third surface is inclined more from the {01-1} plane than the fourth surface in the plane parallel to the first main surface. The fifth surface and the sixth surface are inclined in a same direction as the third surface and the fourth surface from the {01-1} plane in the plane parallel to the first main surface. The optical semiconductor element includes a second semiconductor layer contacting the first surface, the second surface, the third surface, the fourth surface, the fifth surface, and the sixth surface, a first electrode pad provided at a position where the laser portion is interposed between the substrate and the first electrode pad, including a first metal, and electrically connected to the laser portion, a second electrode pad provided at a position where the optical amplifier portion is interposed between the substrate and the second electrode pad, including a second metal, and electrically connected to the optical amplifier portion, and a third electrode pad provided at the second main surface, electrically connected to the substrate, and including a third metal. In plan view, on an outer side of the first electrode pad, the optical semiconductor element includes a first region situated on an extension line of the laser portion on a propagation direction side of light propagating in a straight line inside the laser portion, and a second region overlapping the optical amplifier portion. A ratio of a metal film covering the first semiconductor layer or the second semiconductor layer is lower inside the first region than inside the second region.

The fifth surface and the sixth surface are inclined in the same direction as the third surface and the fourth surface from the {01-1} plane in a plane parallel to the first main surface, and the optical axis of the optical amplifier portion is inclined from a direction perpendicular to the end surface. When the optical axis of the optical amplifier portion is inclined from the direction perpendicular to the end surface, the reflectance at the end surface is lower than that when the optical axis is not inclined. Thus, reflection at the end surface is reduced, and a high output is obtained. Further, between the laser portion and the optical amplifier portion, the optical axes are not on a straight line and the propagation directions of lights are different, but since the second semiconductor layer is provided, light is confined in the mesa and the radiation of light to the outside of the mesa is reduced Thus, the output can be improved. In addition, since the ratio of the metal film covering the first semiconductor layer or the second semiconductor layer is lower in the first region than in the second region, the light is easily radiated to the outside before being emitted from the optical semiconductor element. Thus, it is possible to reduce a decrease in the evaluation accuracy of the characteristics due to the output of the light radiated to the outside of the mesa, and to evaluate the characteristics with high accuracy.

[2] In [1], a ratio of the first semiconductor layer or the second semiconductor layer covered by the metal film in the first region may be 60% or less in terms of an area ratio. In this case, the light radiated to the outside of the mesa is more likely to be radiated to the outside before being emitted from the optical semiconductor element.

[3] In [2], a ratio of the first semiconductor layer or the second semiconductor layer covered by the second electrode pad in the first region may be 40% to 60% in terms of an area ratio. In this case, the connection of the bonding wire to the second electrode pad and the contact of the probe can be easily performed.

[4] In [1], a ratio of the first semiconductor layer or the second semiconductor layer covered by the metal film in the first region may be 20% or less in terms of an area ratio. In this case, the light radiated to the outside of the mesa is likely to be radiated to the outside before being emitted from the optical semiconductor element.

[5] In any one of [1] to [4], the optical semiconductor element may include a frame portion connected to the second electrode pad, including fourth metal, and provided along an end portion of the first semiconductor layer in plan view. In this case, high rigidity is easily obtained.

[6] In any one of [1] to [5], the optical semiconductor element may include an identification mark provided apart from the second electrode pad so as to be visually confirmable and including a fifth metal. In this case, the optical semiconductor element can be distinguished from other optical semiconductor elements.

[7] In any one of [1] to [6], the substrate may be an indium phosphide substrate. In this case, high output is easily obtained.

### DETAILS OF EMBODIMENTS OF PRESENT DISCLOSURE

### First Embodiment

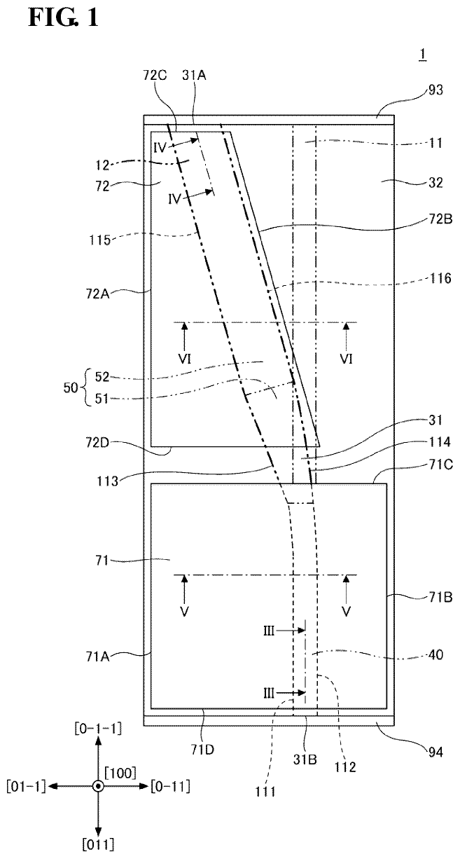

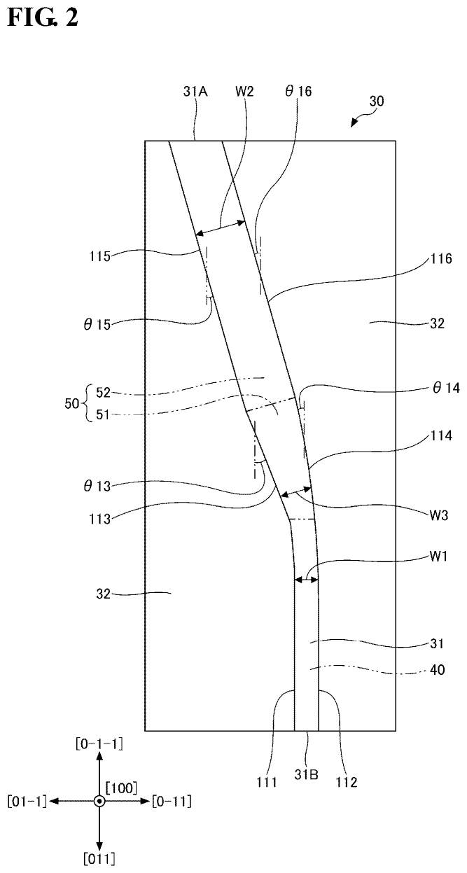

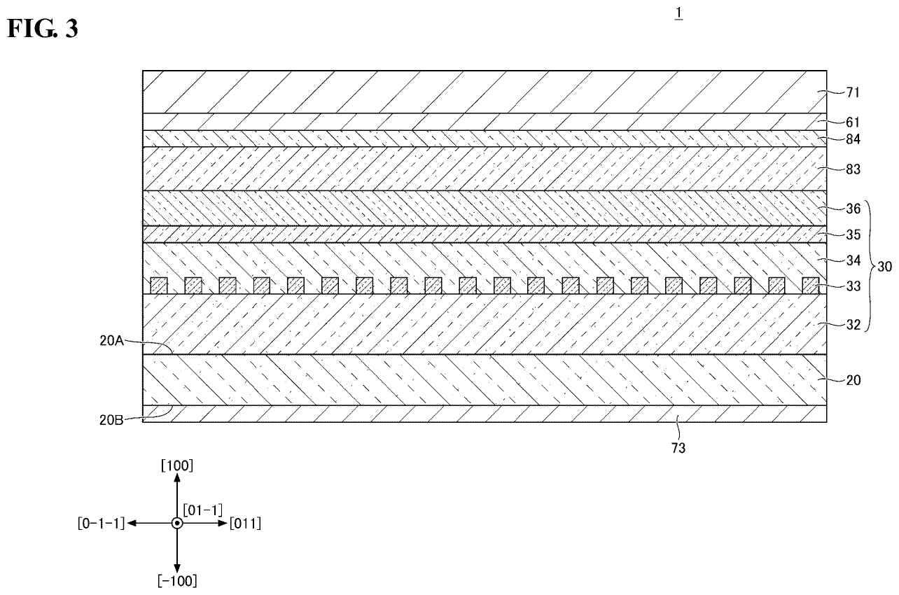

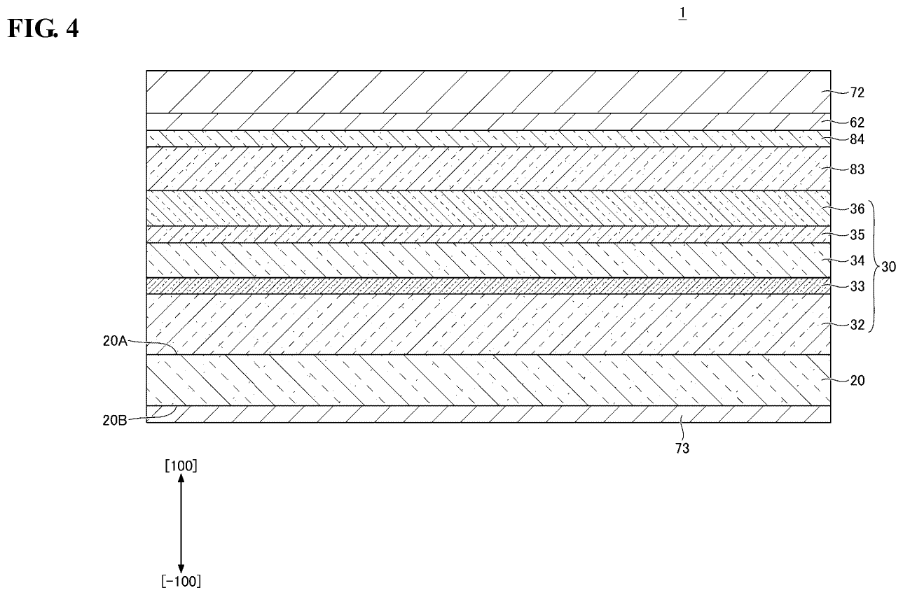

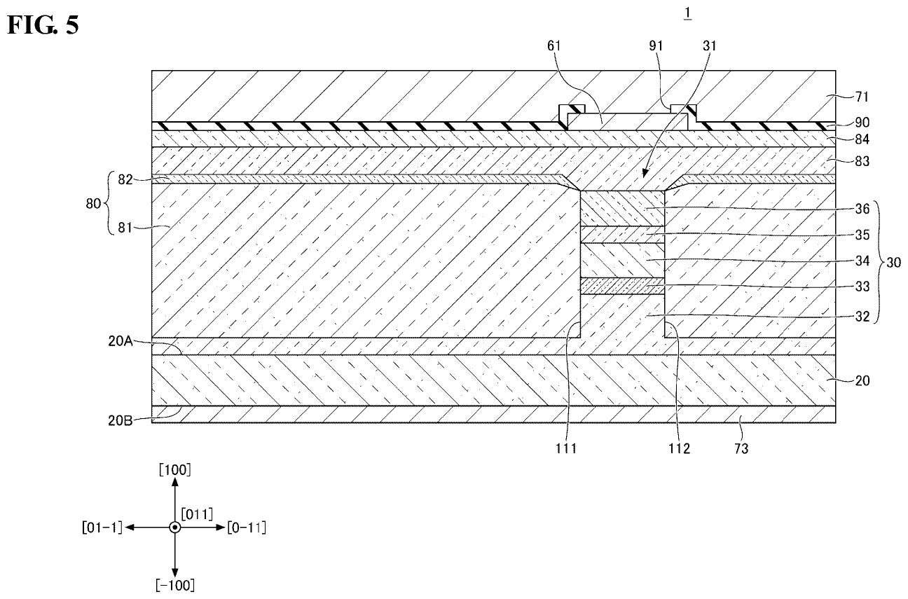

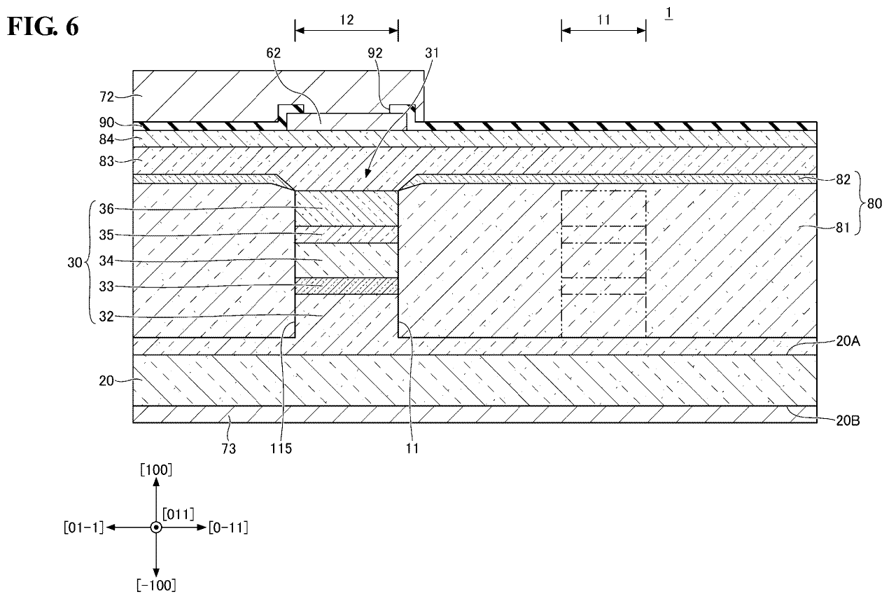

The first embodiment will be described. A first embodiment relates to an optical semiconductor element. FIG. 1 is a plan view showing an optical semiconductor element according to a first embodiment. FIG. 2 is a plan view showing the configuration of the first semiconductor layer in the first embodiment. FIG. 3 to FIG. 6 are cross-sectional views showing an optical semiconductor element according to a first embodiment. FIG. 3 corresponds to a cross-sectional view along the line III-III in FIG. 1. FIG. 4 corresponds to a cross-sectional view along the line IV-IV in FIG. 1. FIG. 5 corresponds to a cross-sectional view along the line V-V in FIG. 1. FIG. 6 corresponds to a cross-sectional view along the line VI-VI in FIG. 1. In FIG. 1, a p-type block layer 81, an n-type block layer 82, a p-type semiconductor layer 83, a contact layer 84, and an insulating film 90, which will be described later, are omitted.

As shown in FIG. 1 to FIG. 6, an optical semiconductor element 1 according to the first embodiment mainly includes a substrate 20, a semiconductor layer 30, and a semiconductor layer 80.

Substrate 20 is, for example, an n-type indium phosphide (InP) substrate. Substrate 20 has a first main surface 20A and a second main surface 20B which is opposite to first main surface 20A. Substrate 20 is doped with silicon (Si) or sulfur (S) at a concentration of 1.0×10¹⁸ cm⁻³, for example. The plane orientation of first main surface 20A is (100), and the plane orientation of second main surface 20B is (−100). In the present disclosure, the plan view means that an object is viewed from a direction perpendicular to first main surface 20A.

Semiconductor layer 30 is provided on first main surface 20A. Semiconductor layer 30 includes a buffer layer 32, a diffraction grating layer 33, an n-type cladding layer 34, an active layer 35, and a p-type cladding layer 36. Semiconductor layer 30 is an example of a first semiconductor layer.

Buffer layer 32 is provided on substrate 20. Buffer layer 32 is, for example, an n-type InP layer having a thickness of about 300 nm. Buffer layer 32 is doped with Si at a concentration of 3.0×10¹⁷ cm⁻³, for example. Buffer layer 32 inherits the crystal orientation of substrate 20.

Diffraction grating layer 33 is provided on buffer layer 32. Diffraction grating layer 33 is, for example, an n-type gallium indium arsenide phosphide (GaInAsP) layer having a thickness of about 50 nm. The emission wavelength λg of diffraction grating layer 33 at room temperature is about 1.15 μm. Diffraction grating layer 33 is doped with Si at a concentration of 5.0×10¹⁷ cm⁻³, for example. Diffraction grating layer 33 inherits the crystal orientation of buffer layer 32.

N-type cladding layer 34 is provided on diffraction grating layer 33 and buffer layer 32. N-type cladding layer 34 covers diffraction grating layer 33. N-type cladding layer 34 is, for example, an n-type InP layer having a thickness of about 500 nm. N-type cladding layer 34 is doped with Si at a concentration of 5.0×10¹⁷ cm⁻³, for example, N-type cladding layer 34 inherits the crystal orientation of diffraction grating layer 33 and buffer layer 32.

Active layer 35 is provided on n-type cladding layer 34. Active layer 35 includes a quantum well layer and two barrier layers interposing the quantum well layer. The quantum well layer is, for example, a GaInAsP layer or an aluminum gallium indium arsenide (AlGaInAs) layer having a thickness of about 80 nm. The barrier layer is, for example, a GaInAsP layer or an AlGaInAs layer having a thickness of about 50 nm. The emission wavelength ag of the barrier layer at room temperature is about 1.15 μm.

Active layer 35 inherits the crystal orientation of n-type cladding layer 34.

P-type cladding layer 36 is provided on active layer 35. P-type cladding layer 36 is, for example, a p-type InP layer having a thickness of about 300 nm. P-type cladding layer 36 is doped with zinc (Zn) at a concentration of, for example, 3.0×10¹⁷ cm⁻³. P-type cladding layer 36 inherits the crystal orientation of active layer 35.

Semiconductor layer 30 inherits the crystal orientation of substrate 20. The crystal orientation in the following description is the crystal orientation of substrate 20. A mesa 31 is formed in semiconductor layer 30. Mesa 31 is formed so that a portion of buffer layer 32 is exposed. The height of mesa 31 is, for example, about 1000 nm. Mesa 31 includes a laser portion 40 and an optical amplifier portion 50. As will be described in detail later, as shown in FIG. 1 and FIG. 2, laser portion 40 extends in parallel to the [0-1-1] direction, and optical amplifier portion 50 extends in parallel to a direction inclined by 6° to 8° from the [0-1-1] direction toward the [01-1] direction. Optical amplifier portion 50 is connected to the end portion of laser portion 40 at the [0-1-1] side. The dimension of laser portion 40 in the direction parallel to the [0-1-1] direction is, for example, 350 μm to 1000 μm. The dimension of optical amplifier portion 50 in the direction parallel to the [0-1-1] direction is, for example, 500 μm to 1800 μm.

Laser portion 40 has a first surface 111 and a second surface 112 perpendicular to first main surface 20A. The plane orientation of first surface 111 is (01-1), and the plane orientation of second surface 112 is (0-11). That is, first surface 111 and second surface 112 are parallel to the {01-1} plane. A first distance W1 between first surface 111 and second surface 112 is, for example, 1.5 μm to 2.5 μm.

Optical amplifier portion 50 includes a tapered portion 51 and a parallel portion 52. Tapered portion 51 is connected to an end portion of laser portion 40 on the [0-1-1] side, and parallel portion 52 is connected to an end portion of tapered portion 51 opposite to laser portion 40.

Tapered portion 51 has a third surface 113 and a fourth surface 114 perpendicular to first main surface 20A. Third surface 113 is connected to first surface 111, and fourth surface 114 is connected to second surface 112. Third surface 113 and fourth surface 114 are inclined in the same direction from the (01-1) plane and the (0-11) plane, respectively, in a plane parallel to first main surface 20A. The direction in which third surface 113 and fourth surface 114 are inclined is a direction parallel to the (100) plane. The inclination of third surface 113 from the (01-1) plane is larger than the inclination of fourth surface 114 from the (0-11) plane. That is, third surface 113 is inclined more from the {01-1} plane than fourth surface 114 in the plane parallel to first main surface 20A. Thus, a third distance W3 between third surface 113 and fourth surface 114 gradually increases as the distance from laser portion 40 increases. The angle formed by third surface 113 and the (01-1) plane is an angle θ13, the angle formed by fourth surface 114 and the (0-11) plane is an angle θ14, and angle θ13 is larger than angle θ14. In the present disclosure, the angle formed by two planes is 0° to 90°. The angle between the two surfaces can be measured by, for example, microscopic observation.

Parallel portion 52 has a fifth surface 115 and a sixth surface 116 perpendicular to first main surface 20A. Fifth surface 115 and sixth surface 116 are parallel to each other. A second distance W2 between fifth surface 115 and sixth surface 116 is larger than first distance W1.

From the opposite perspective, first distance W1 is smaller than second distance W2. Second distance W2 is, for example, 2.0 μm to 10 μm. Fifth surface 115 and sixth surface 116 are inclined in the same direction as third surface 113 and fourth surface 114 from the (01-1) plane and the (0-11) plane, respectively, in a plane parallel to first main surface 20A. For example, fifth surface 115 and sixth surface 116 are inclined by 6° to 8° in the same direction as third surface 113 and fourth surface 114 from the (01-1) plane and the (0-11) plane, respectively, in the plane parallel to first main surface 20A. The angle formed by fifth surface 115 and the (01-1) plane is an angle θ15, the angle formed by sixth surface 116 and the (0-11) plane is an angle θ16, and angle θ15 and angle θ16 are equal to each other and are, for example, 6° to 8°.

In the first embodiment, third surface 113 and fifth surface 115 are inclined such that the normal vectors thereof are directed between the [01-1] direction and the [011] direction, and fourth surface 114 and sixth surface 116 are inclined such that the normal vectors thereof are directed between the [0-11] direction and the [0-1-1] direction.

Fifth surface 115 is inclined from the (01-1) plane less than third surface 113 in a plane parallel to first main surface 20A. From the opposite perspective, third surface 113 is inclined from the (01-1) plane more than fifth surface 115 in the plane parallel to first main surface 20A. For example, third surface 113 is inclined from the (01-1) plane more than fifth surface 115 by more than 0° and equal to or less than 1° in a plane parallel to first main surface 20A. The angle θ13 is larger than the angle θ15, and for example, the difference between the angle θ13 and the angle θ15 is more than 0° and equal to or less than 1°.

Sixth surface 116 is inclined from the (0-11) plane more than fourth surface 114 in a plane parallel to first main surface 20A. From the opposite perspective, fourth surface 114 is inclined smaller from the (0-11) plane than sixth surface 116 in a plane parallel to first main surface 20A. For example, fourth surface 114 is inclined from the (0-11) plane less than sixth surface 116 by more than 0° and equal to or less than 1° in a plane parallel to first main surface 20A. The angle θ16 is larger than the angle θ14, and for example, the difference between the angle θ16 and the angle θ14 is more than 0° and equal to or less than 1°.

For example, a difference between the angle θ13 and the angle θ15 is equal to a difference between the angle θ16 and the angle θ14, and at the boundary between tapered portion 51 and parallel portion 52, the optical axis of tapered portion 51 and the optical axis of parallel portion 52 are connected to each other and are parallel to each other. The optical axis of parallel portion 52 is inclined, for example, by 6° to 8° from the [0-1-1] direction.

As shown in FIG. 3, in laser portion 40, a diffraction grating having a constant period is formed in diffraction grating layer 33. On the other hand, as shown in FIG. 4, in optical amplifier portion 50, diffraction grating layer 33 is not formed with a diffraction grating, and the entire top surface of buffer layer 32 is covered with diffraction grating layer 33 in mesa 31.

Semiconductor layer 80 is provided on the side of mesa 31 so as to bury mesa 31. Semiconductor layer 80 includes p-type block layer 81 and n-type block layer 82. Semiconductor layer 80 is in contact with first surface 111, second surface 112, third surface 113, fourth surface 114, fifth surface 115, and sixth surface 116. Semiconductor layer 80 is an example of a second semiconductor layer. At least a portion of the top surface of p-type cladding layer 36 is exposed from semiconductor layer 80.

P-type block layer 81 is provided on buffer layer 32. P-type block layer 81 is in contact with first surface 111, second surface 112, third surface 113, fourth surface 114, fifth surface 115, and sixth surface 116. P-type block layer 81 is in contact with the side surfaces of buffer layer 32, diffraction grating layer 33, n-type cladding layer 34, active layer 35, and p-type cladding layer 36. P-type block layer 81 is, for example, a p-type InP layer in which the thickest portion is 1000 nm to 1500 nm. P-type block layer 81 is doped with Zn at a concentration of, for example, 1.0×10¹⁷ cm⁻³ to 1.0×10¹⁸ cm⁻³. Chlorine (Cl) may be added to a portion of p-type block layer 81.

N-type block layer 82 is provided on p-type block layer 81. N-type block layer 82 is, for example, an n-type InP layer in which the thickest portion is 300 nm to 500 nm. N-type block layer 82 is doped with Si at a concentration of, for example, about 5.0×10¹⁸ cm⁻³. Cl may be added to a portion of n-type block layer 82.

Optical semiconductor element 1 further includes p-type semiconductor layer 83, contact layer 84, a first electrode 61, a second electrode 62, a first electrode pad 71, a second electrode pad 72, a third electrode pad 73, insulating film 90, an antireflection film 93, and a high reflection film 94.

P-type semiconductor layer 83 is provided on p-type cladding layer 36 and n-type block layer 82. P-type semiconductor layer 83 is, for example, a p-type InP layer in which the thickest portion is 2500 nm to 3500 nm. P-type semiconductor layer 83 is doped with Zn at a concentration of, for example, 1.0×10¹⁸ cm⁻³ to 2.0×10¹⁸ cm⁻³. P-type semiconductor layer 83 may function as a portion of p-type cladding layer 36.

Contact layer 84 is provided on p-type semiconductor layer 83. Contact layer 84 includes a p-type GaInAsP layer and a p-type indium gallium arsenide (InGaAs) layer. The GaInAsP layer is provided on p-type semiconductor layer 83. For example, the GaInAsP layer is about 200 nm thick, and the GaInAsP layer is doped with Zn at a concentration of about 2.0×10¹⁸ cm⁻³. The InGaAs layer is provided on the GaInAsP layer. For example, the InGaAs layer is about 300 nm thick, and the InGaAs layer is doped with Zn at a concentration of about 8.0×10¹⁸ cm⁻³. The band gap of contact layer 84 is smaller than the band gap of p-type semiconductor layer 83. Contact layer 84 of laser portion 40 is insulated and separated from contact layer 84 of optical amplifier portion 50.

First electrode 61 is provided on contact layer 84 in laser portion 40. First electrode 61 is provided so as to overlap laser portion 40 in plan view. For example, first surface 111 and second surface 112 are located inside the outline of first electrode 61 in the plan view.

Second electrode 62 is provided on contact layer 84 in optical amplifier portion 50. Second electrode 62 is provided so as to overlap optical amplifier portion 50 in plan view. For example, third surface 113, fourth surface 114, fifth surface 115, and sixth surface 116 are located inside the outline of second electrode 62 in the plan view.

Insulating film 90 covers the top surface of contact layer 84, the top surface and the side surface of first electrode 61, and the top surface and the side surface of second electrode 62. Insulating film 90 is, for example, a silicon-oxide (SiO₂) film, a silicon-oxynitride (SiON) film, or a silicon-nitride (SiN) film. An opening portion 91 through which a portion of the top surface of first electrode 61 is exposed and an opening portion 92 through which a portion of the top surface of second electrode 62 is exposed are formed in insulating film 90.

First electrode pad 71 and second electrode pad 72 are provided on insulating film 90. First electrode pad 71 is provided at a position where laser portion 40 is interposed between first electrode pad 71 and substrate 20. First electrode pad 71 is in contact with first electrode 61 and is electrically connected to laser portion 40 through first electrode 61. Second electrode pad 72 is provided at a position where optical amplifier portion 50 is interposed between second electrode pad 72 and substrate 20. Second electrode pad 72 is in contact with second electrode 62 and is electrically connected to optical amplifier portion 50 through second electrode 62. First electrode pad 71 and second electrode pad 72 include a metal, and have, for example, a gold (Au) film. The metal included in first electrode pad 71 is an example of a first metal, and the metal included in second electrode pad 72 is an example of a second metal.

First electrode 61 and second electrode 62 are insulated and separated from each other, and first electrode pad 71 and second electrode pad 72 are insulated and separated from each other. Thus, independent voltages can be applied to laser portion 40 and optical amplifier portion 50.

Third electrode pad 73 is provided on second main surface 20B of substrate 20. Third electrode pad 73 is in contact with substrate 20 and is electrically connected to substrate 20. Third electrode pad 73 includes a metal, and has, for example, a gold (Au) film. The metal included in third electrode pad 73 is an example of a third metal.

Mesa 31 includes a first end surface 31A having a plane orientation of (0-1-1) and a second end surface 31B having a plane orientation of (011). Antireflection film 93 covers first end surface 31A, and high reflection film 94 covers second end surface 31B. For example, antireflection film 93 includes an aluminum oxide (Al₂O₃) layer or a silicone oxide (SiO₂) film as a low-refractive-index film and tantalum oxide (Ta₂O₅) layer or titanium dioxide (TiO₂) film as a high-refractive-index film, and the low-refractive-index film is between first end surface 31A and the high-refractive-index film. For example, high reflection film 94 has a multilayer structure in which a structure including an aluminum oxide (Al₂O₃) layer or a silicone oxide (SiO₂) film layer as a low-refractive-index film and tantalum oxide (Ta₂O₅) layer or titanium dioxide (TiO₂) film as a high-refractive-index film, and has the multi-layered structure in which the low-refractive-index film and the high-refractive-index film are stacked from second end surface 31B with repetition cycles of two to five cycles.

Here, the shape of first electrode pad 71 in plan view, that is, the planar shape will be described. The planar shape of first electrode pad 71 is a rectangular shape. The planar shape of first electrode pad 71 has sides 71A and 71B parallel to the [011] direction and sides 71C and 71D parallel to the [01-1] direction. Side 71A is on the [01-1] side of side 71B, and side 71C is on the [0-1-1] side of side 71D. Side 71A is near the end portion of semiconductor layer 30 on the [01-1] side. Side 71B is near the end portion of the [0-11] side of semiconductor layer 30. Side 71C is near the boundary between laser portion 40 and optical amplifier portion 50. Side 71D is near the end portion of semiconductor layer 30 on the [011] side.

Next, the shape of second electrode pad 72 in plan view, that is, the planar shape, will be described. The planar shape of second electrode pad 72 is a trapezoidal shape. The planar shape of second electrode pad 72 has a side 72A parallel to the [011] direction, a side 72B parallel to sixth surface 116, and sides 72C and 72D parallel to the [01-1] direction. Side 72A is on the [01-1] side of side 72B, and side 72C is on the [0-1-1] side of side 72D. Side 72A is near the end portion of semiconductor layer 30 on the [01-1] side. Side 72B is near fourth surface 114 and sixth surface 116. Side 72C is near the end portion of semiconductor layer 30 on the [0-1-1] side. Side 72D is between first electrode pad 71 and parallel portion 52.

In plan view, on an outer side of first electrode pad 71, optical semiconductor device 1 includes a first region 11 on an extension line of laser portion 40 on the propagation direction side of light propagating in a straight-line inside laser portion 40, and a second region 12 overlapping with optical amplifier portion 50. A portion of first region 11 and a portion of second region 12 may overlap each other.

Second electrode pad 72 overlaps with most of optical amplifier portion 50 in plan view, and is provided in most of second region 12. For example, second electrode pad 72 is provided in 80% or more of second region 12 in area ratio in plan view, and covers 80% or more of semiconductor layer 30 in second region 12, that is, optical amplifier portion 50. Second electrode pad 72 may cover 90% or more, or 95% or more, of optical amplifier portion 50 in area ratio in plan view.

On the other hand, side 72B of the planar shape of second electrode pad 72 is near fourth surface 114 and sixth surface 116, and most of first region 11 is not covered by second electrode pad 72. Semiconductor layer 30 or semiconductor layer 80 in first region 11 is not covered with a metal film other than second electrode pad 72. For example, in an area ratio in plan view, a ratio of the metal film in first region 11 may be 20% or less, and a ratio of a portion covered by the metal film in semiconductor layer 30 or semiconductor layer 80 in first region 11 may be 20% or less. In an area ratio in plan view, a ratio of a portion covered by the metal film in semiconductor layer 30 or semiconductor layer 80 in first region 11 may be 10% or less, or 5% or less.

As described above, the ratio of the metal film covering semiconductor layer 30 or semiconductor layer 80 is lower in first region 11 than in second region 12.

In optical semiconductor element 1, a portion including laser portion 40 of mesa 31 functions as a DFB laser in plan view, and a portion including optical amplifier portion 50 of mesa 31 functions as an SOA in plan view.

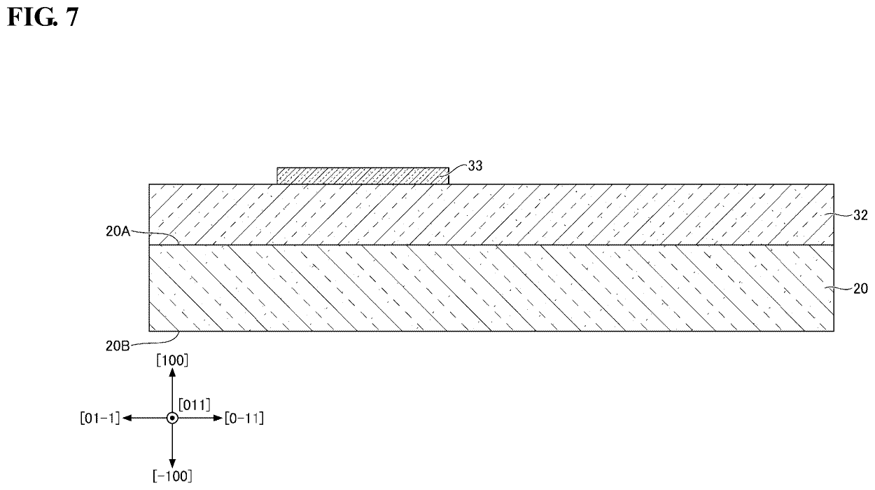

Next, a method of manufacturing optical semiconductor element 1 according to the first embodiment will be described. FIG. 7 to FIG. 16 are cross-sectional views showing a manufacturing method of optical semiconductor element 1 according to the first embodiment. FIG. 7 to FIG. 16 show the change in the cross section along the line V-V in FIG. 1.

First, as shown in FIG. 7, substrate 20 having first main surface 20A and second main surface 20B is prepared, and buffer layer 32 is formed on first main surface 20A. Next, diffraction grating layer 33 is formed on buffer layer 32. Diffraction grating layer 33 may be formed wider than the final dimensions. In the portion included in laser portion 40, the diffraction grating is formed in diffraction grating layer 33 (see FIG. 3), and in the portion included in optical amplifier portion 50, diffraction grating layer 33 covers the entire top surface of buffer layer 32.

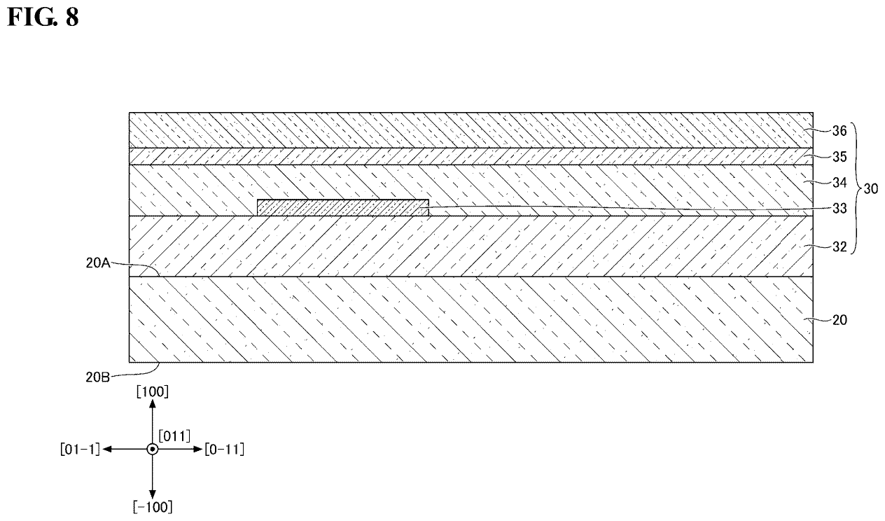

Next, as shown in FIG. 8, n-type cladding layer 34 is formed on diffraction grating layer 33 and buffer layer 32. N-type cladding layer 34 covers diffraction grating layer 33. Next, active layer 35 is formed on n-type cladding layer 34, and p-type cladding layer 36 is formed on active layer 35.

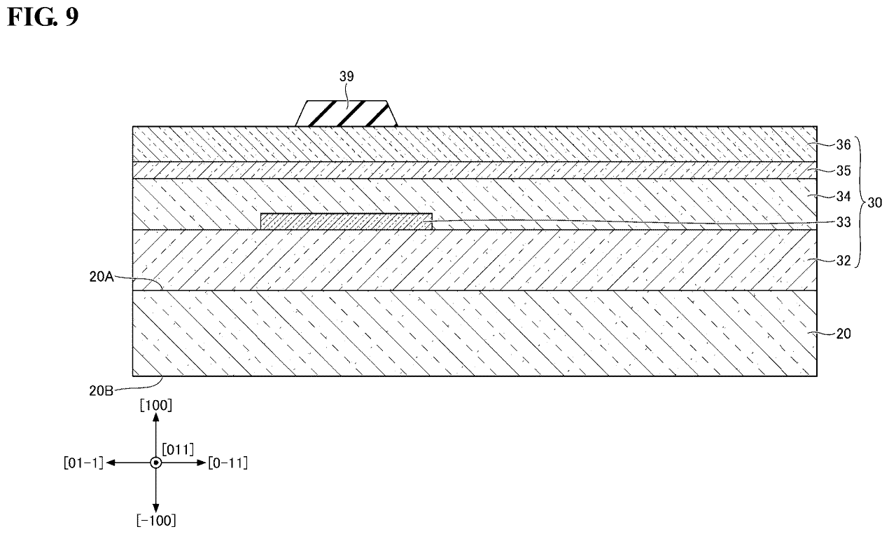

Next, as shown in FIG. 9, a mask 39 is formed on p-type cladding layer 36. Mask 39 is formed on a region where mesa 31 is formed. Mask 39 is, for example, a side SiO₂ film.

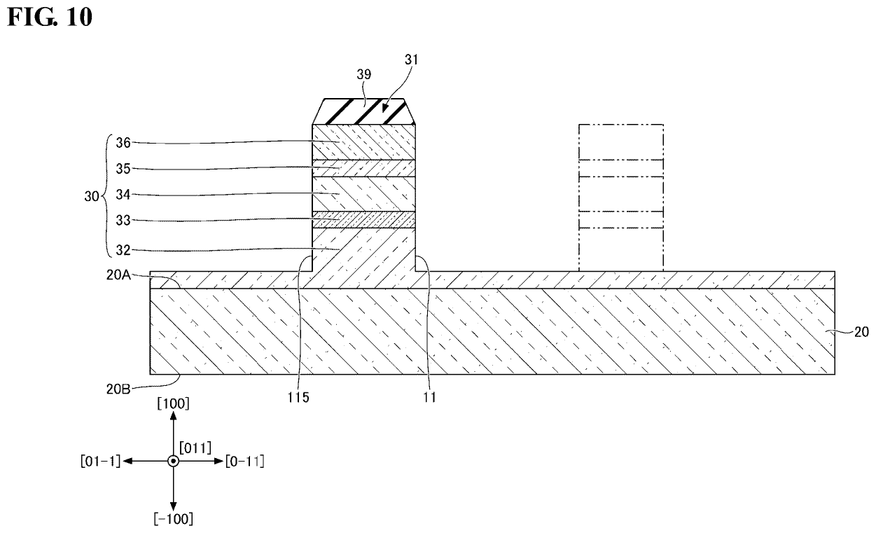

Next, as shown in FIG. 10, p-type cladding layer 36, active layer 35, n-type cladding layer 34, diffraction grating layer 33, and a portion of buffer layer 32 are dry-etched using mask 39 as an etching mask. As a result, mesa 31 is formed. Mesa 31 includes laser portion 40 and optical amplifier portion 50, and optical amplifier portion 50 includes tapered portion 51 and parallel portion 52. In addition, laser portion 40 has first surface 111 and second surface 112, tapered portion 51 has third surface 113 and fourth surface 114, and parallel portion 52 has fifth surface 115 and sixth surface 116. As the dry etching, for example, reactive ion etching (RIE) using silicon tetrachloride (SiCl₄) is performed.

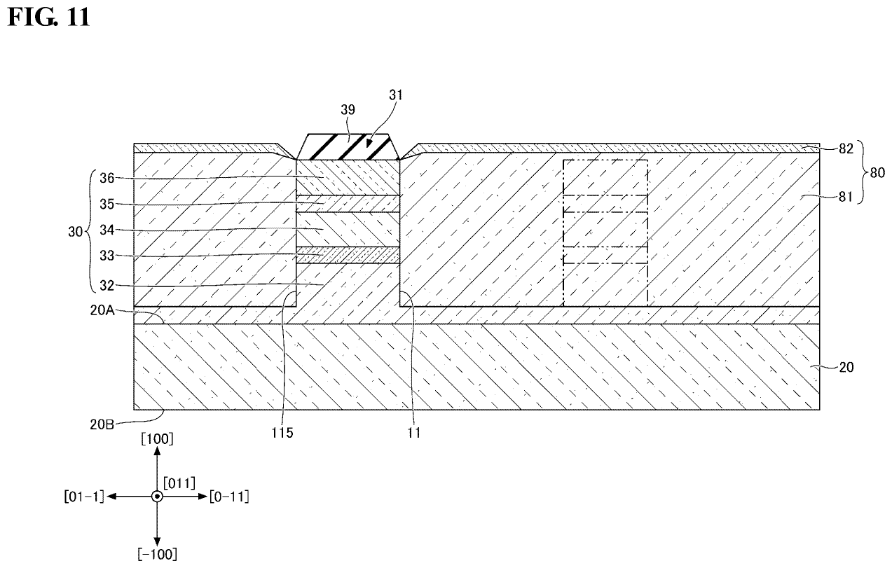

Next, as shown in FIG. 11, p-type block layer 81 is formed on buffer layer 32 exposed from mesa 31 and n-type block layer 82 is formed on p-type block layer 81 using mask 39 as a growth mask. As a result, mesa 31 is buried with semiconductor layer 80 including p-type block layer 81 and n-type block layer 82. Semiconductor layer 80 is in contact with first surface 111, second surface 112, third surface 113, fourth surface 114, fifth surface 115, and sixth surface 116.

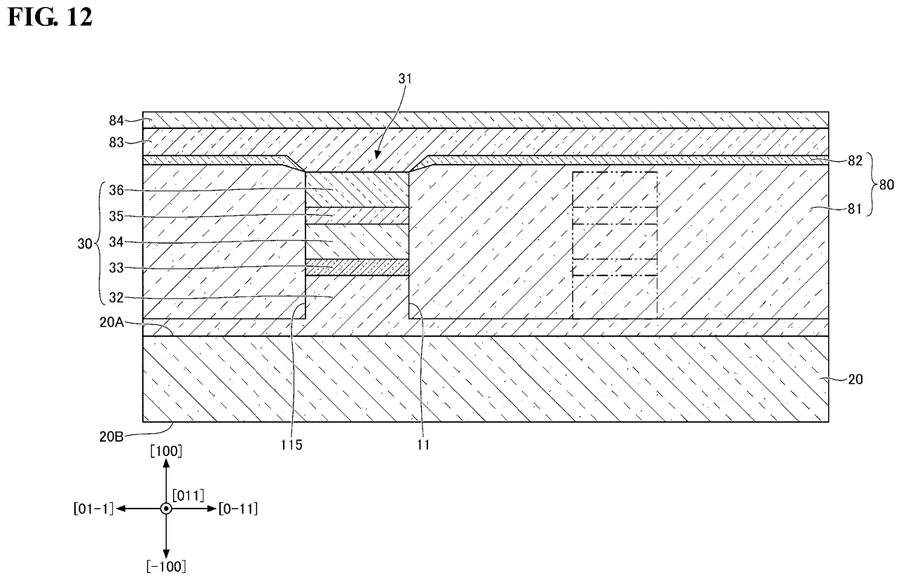

Next, as shown in FIG. 12, mask 39 is removed. Mask 39 can be removed by using, for example, hydrofluoric acid (HF). Next, p-type semiconductor layer 83 is formed on p-type cladding layer 36 and n-type block layer 82, and contact layer 84 is formed on p-type semiconductor layer 83. P-type semiconductor layer 83 is integrated with p-type cladding layer 36.

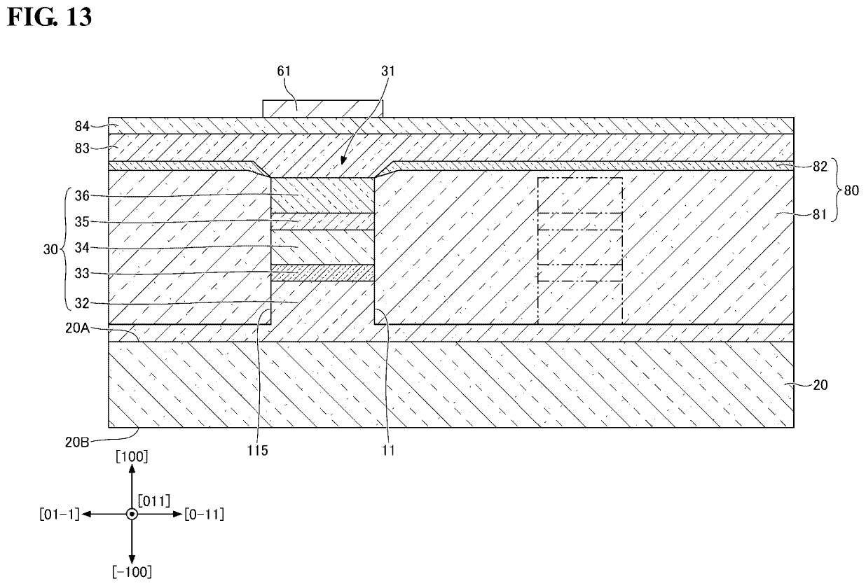

Next, as shown in FIG. 13, first electrode 61 is formed on contact layer 84. Second electrode 62 is also formed at the same time as first electrode 61 is formed (see FIG. 4 and FIG. 6).

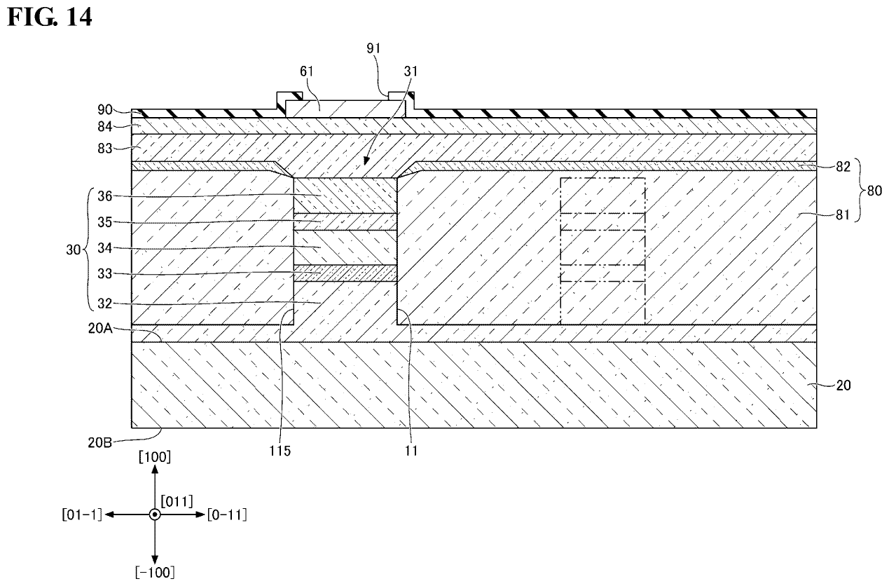

Next, as shown in FIG. 14, insulating film 90 is formed which covers the top surface of contact layer 84, the top surface and the side surface of first electrode 61, and the top surface and the side surface of second electrode 62, and opening portion 91 is formed in insulating film 90 which exposes a portion of the top surface of first electrode 61. At the same time as opening portion 91 is formed, opening portion 92 is formed which exposes a portion of the top surface of second electrode 62 (see FIG. 6).

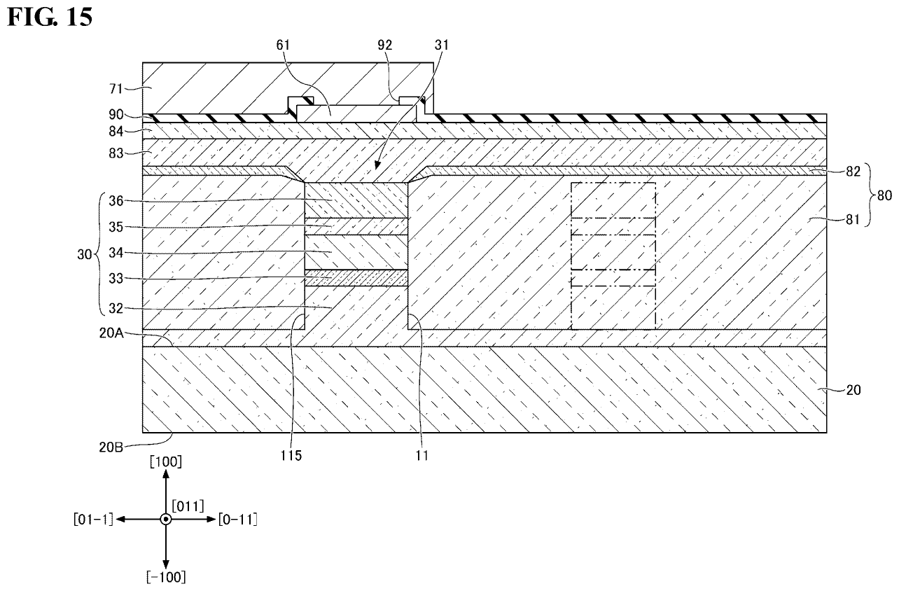

Next, as shown in FIG. 15, first electrode pad 71 is formed on insulating film 90. First electrode pad 71 is in contact with first electrode 61. At the same time as opening portion 91 is formed, second electrode pad 72 in contact with second electrode 62 is also formed (see FIG. 4 and FIG. 6).

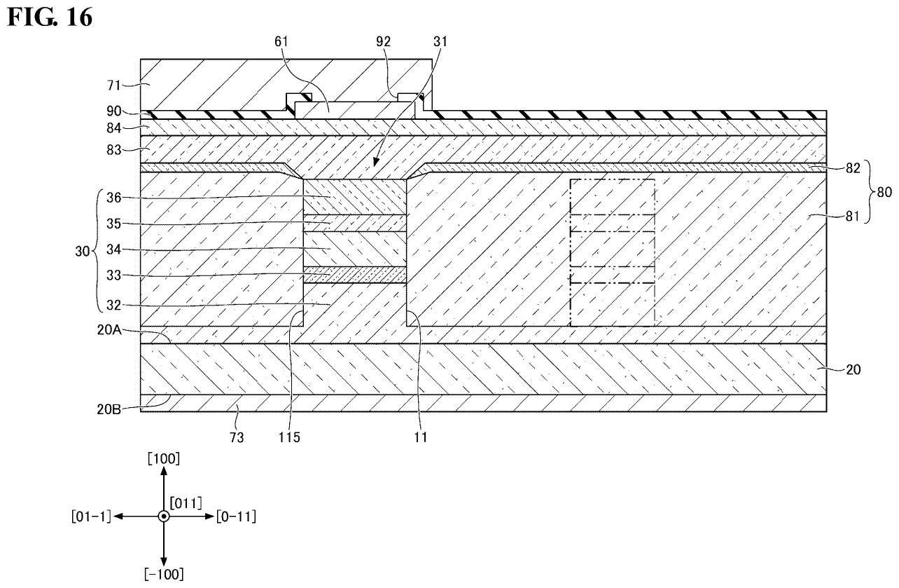

Next, as shown in FIG. 16, substrate 20 is polished from second main surface 20B. Next, third electrode pad 73 in contact with substrate 20 is formed on second main surface 20B.

Next, antireflection film 93 covering first end surface 31A of mesa 31 and high reflection film 94 covering second end surface 31B are formed.

In this way, optical semiconductor element 1 according to the first embodiment can be manufactured.

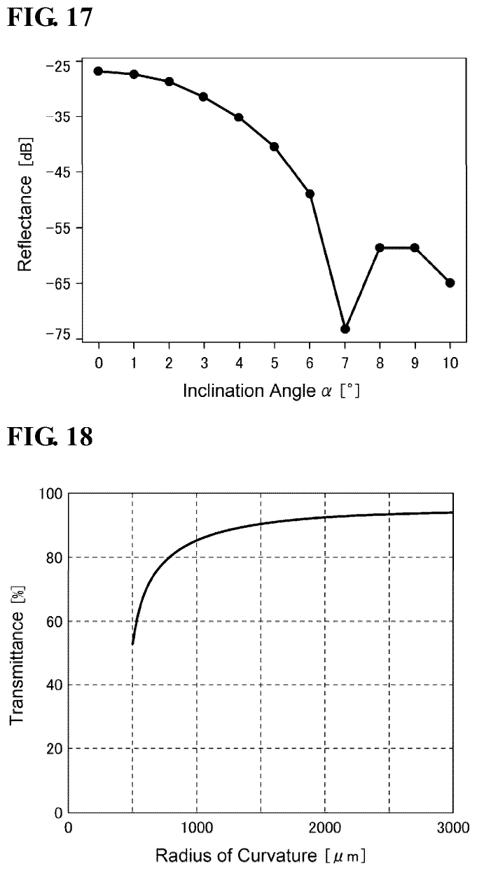

In optical semiconductor element 1, when a voltage is applied across first electrode pad 71 and third electrode pad 73, light is generated in laser portion 40. When a voltage is applied across second electrode pad 72 and third electrode pad 73, the output is amplified by optical amplifier portion 50, and laser light is emitted from first end surface 31A. Fifth surface 115 and sixth surface 116 are inclined in the same direction as third surface 113 and fourth surface 114 from the (01-1) plane and the (0-11) plane, respectively, in a plane parallel to first main surface 20A, and the optical axis of optical amplifier portion 50 is inclined from a direction perpendicular to first end surface 31A. As shown in FIG. 17, when the optical axis of optical amplifier portion 50 is inclined from the direction perpendicular to first end surface 31A, that is, when an inclination angle α is larger than 0°, the reflectance at first end surface 31A is lower than when the optical axis is not inclined, that is, when inclination angle α is 0°. Thus, in optical semiconductor element 1, reflection at first end surface 31A is reduced, and a high output is obtained. When inclination angle α is 6° to 8°, the reflectance is particularly low, and an excellent output can be obtained. FIG. 17 is a diagram showing the relationship between inclination angle α and the reflectance at first end surface 31A. The reflectance is expressed in logarithm.

Between laser portion 40 and optical amplifier portion 50, the optical axes are not on a straight line and the propagation directions of light are different, but since semiconductor layer 80 is provided, light is confined in mesa 31 and the radiation of light to the outside of mesa 31 is reduced. For example, the radiation of light to the outside of mesa 31 is reduced to 3% or less.

Even when light is radiated to the outside of mesa 31, the light is unlikely to reach antireflection film 93. This is because second electrode pad 72 is locally provided between laser portion 40 and antireflection film 93, and most of first region 11 is not covered by the metal film such as second electrode pad 72. As the range of first region 11 covered by the metal film is wider, light is more likely to reach antireflection film 93 while being reflected between the metal film and third electrode pad 73. In contrast, when most of first region 11 is not covered with the metal film, even when light is reflected by third electrode pad 73, the light is not reflected by the opposite surface and is likely to exit to the outside of optical semiconductor element 1. Thus, even when light is radiated to the outside of mesa 31, the light is unlikely to reach antireflection film 93.

When the light radiated to the outside of mesa 31 reaches antireflection film 93, the light is also output from optical semiconductor element 1 in addition to the light output from mesa 31. Thus, the evaluation accuracy of the characteristics of optical semiconductor element 1 may be reduced. In contrast, according to the embodiment, the output from optical semiconductor element 1 of the light radiated to the outside of mesa 31 can be reduced, and thus the characteristics can be evaluated with high accuracy. Since the ratio of the portion covered with the metal film in semiconductor layer 30 or semiconductor layer 80 in first region 11 is 20% or less, the light radiated to the outside of mesa 31 is particularly easily radiated to the outside before being emitted from optical semiconductor element 1.

As described above, the optical axes of laser portion 40 and optical amplifier portion 50 are not aligned with each other, and the propagation directions of light are different from each other. In the plan view, the optical axis passes through the center of the cross section perpendicular to the propagation direction of light in mesa 31. As the radius of curvature of tapered portion 51 of the optical axis or the like is smaller, optical semiconductor element 1 can be more easily miniaturized, but light is more easily radiated to the outside of mesa 31. The radius of curvature of the optical axis is not necessarily constant, but optical semiconductor element 1 can be easily miniaturized when the maximum value of the radius of curvature of the optical axis is 2500 μm or less. When the maximum value of the radius of curvature of the optical axis is 2000 μm or less, optical semiconductor element 1 can be more easily miniaturized. On the other hand, when the minimum value of the radius of curvature of the optical axis is 1500 μm or more, the radiation of light to the outside of mesa 31 is easily reduced. Thus, the radius of curvature of the optical axis is, for example, 1500 μm to 2500 μm, and may be 1500 μm to 2000 μm. The radiation of light to the outside of mesa 31 is, for example, 5% or less, and may be 3% or less. In addition, when the radius of curvature of the optical axis continuously changes, it is easy to reduce the coupling loss due to the mode mismatch in the connection portion between the straight line region and the curved region such as tapered portion 51.

Here, the relationship between the radius of curvature of tapered portion 51 and the transmittance of light from laser portion 40 to optical amplifier portion 50 will be described. FIG. 18 is a diagram showing the relationship between the radius of curvature of tapered portion 51 and the transmittance of light from laser portion 40 to optical amplifier portion 50. In the example shown in FIG. 18, the transmittance increases as the radius of curvature increases. This indicates that the radiation of light to the outside of mesa 31 is reduced as the radius of curvature increases. However, when the radius of curvature is larger than 2500 μm, the change in transmittance is small. When the radius of curvature is less than 1500 μm, the transmittance is less than 95%.

For example, bonding wires are connected to first electrode pad 71 and second electrode pad 72. A probe of an inspection apparatus may be brought into contact with first electrode pad 71 and second electrode pad 72.

It is noted that, the material of substrate 20 is not limited, but substrate 20 is an InP substrate, and thus a high output is easily obtained.

### Second Embodiment

The second embodiment will be described. The second embodiment is different from the first embodiment mainly in the configuration of the metal film on semiconductor layer 80.

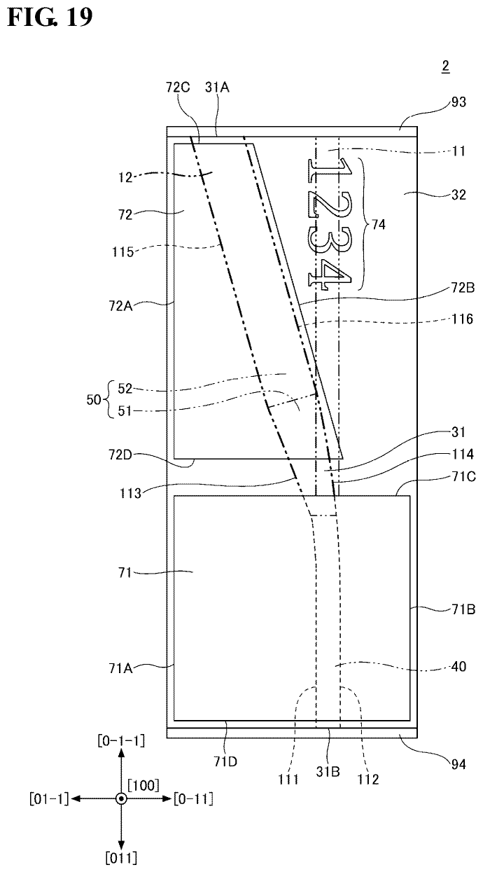

FIG. 19 is a plan view showing an optical semiconductor element according to a second embodiment. In FIG. 19, p-type block layer 81, n-type block layer 82, p-type semiconductor layer 83, contact layer 84, and insulating film 90 are omitted.

As shown in FIG. 19, an optical semiconductor element 2 according to the second embodiment has an identification mark 74 provided on insulating film 90. Identification mark 74 is provided so as to be visually recognizable. Identification mark 74 includes a metal, and has, for example, an Au film. For example, identification mark 74 is made of the same material as second electrode pad 72. A portion of identification mark 74 may be in a portion of first region 11. Identification mark 74 indicates, for example, a number, a character, or a symbol. For example, identification mark 74 may be in a range of 10% or less of first region 11 in area ratio in plan view. For example, in an area ratio in plan view, a ratio of the metal film in first region 11 may be 30% or less, and a ratio of a portion covered by the metal film in semiconductor layer 30 or semiconductor layer 80 in first region 11 may be 30% or less. As in the first embodiment, the ratio of the metal film covering semiconductor layer 30 or semiconductor layer 80 is lower in first region 11 than in second region 12. The metal included in identification mark 74 is an example of a fifth metal.

The other configurations of the second embodiment are the same as those of the first embodiment. The second embodiment can also provide the same effect as that of the first embodiment. Further, optical semiconductor element 2 can be identified from other optical semiconductor elements by providing identification mark 74.

### Third Embodiment

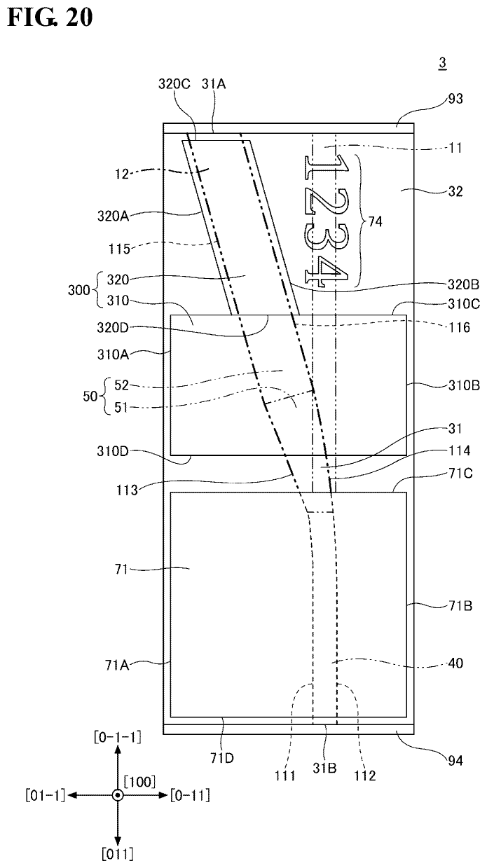

The third embodiment will be described. The third embodiment is different from the second embodiment mainly in the configuration of the second electrode pad. FIG. 20 is a plan view showing an optical semiconductor element according to a third embodiment. In FIG. 20, p-type block layer 81, n-type block layer 82, p-type semiconductor layer 83, contact layer 84, and insulating film 90 are omitted.

As shown in FIG. 20, an optical semiconductor element 3 according to the third embodiment has a second electrode pad 300 instead of second electrode pad 72. Second electrode pad 300 includes a first pad region 310 having a rectangular planar shape and a second pad region 320 having a parallelogram planar shape. First pad region 310 and second pad region 320 are connected to each other.

The planar shape of first pad region 310 has sides 310A and 310B parallel to the [011] direction and sides 310C and 310D parallel to the [01-1] direction. Side 310A is on the [01-1] side of side 310B, and side 310C is on the [0-1-1] side of side 310D.

Side 310A is near the end portion of semiconductor layer 30 on the [01-1] side. Side 310B is near the end portion of the [0-11] side of semiconductor layer 30. Side 310C is between first electrode pad 71 and identification mark 74. Side 310D is between first electrode pad 71 and parallel portion 52. For example, the lengths of sides 310A and 310B are 180 μm to 380 μm, and the lengths of sides 310C and 310D are 100 μm to 800 μm. First pad region 310 occupies about 50% of first region 11 in area ratio in plan view.

The planar shape of second pad region 320 has a side 320A parallel to fifth surface 115, a side 320B parallel to sixth surface 116, and sides 320C and 320D parallel to the [01-1] direction. Side 320A is on the [01-1] side of side 320B, and side 320C is on the [0-1-1] side of side 320D. Side 320A is near fifth surface 115. Side 320B is near sixth surface 116. Side 320C is near the end portion of semiconductor layer 30 on the [0-1-1] side. Side 320D overlaps side 310C.

Second electrode pad 300 overlaps most of optical amplifier portion 50 in plan view and is provided in most of second region 12. For example, second electrode pad 300 is provided in 80% or more of second region 12 in area ratio in plan view, and covers 80% or more of semiconductor layer 30 in second region 12, that is, optical amplifier portion 50. Second electrode pad 300 may cover 90% or more or 95% or more of optical amplifier portion 50 in area ratio in plan view.

On the other hand, side 320B of the planar shape of second pad region 320 of second electrode pad 300 is near sixth surface 116, and first region 11 is away from second pad region 320. In addition, identification mark 74 and first pad region 310 are present in the portion of first region 11, but semiconductor layer 30 or semiconductor layer 80 in first region 11 is not covered with a metal film other than identification mark 74 or second electrode pad 300. For example, in an area ratio in plan view, a ratio of the metal film in first region 11 may be 60% or less, and a ratio of a portion covered by the metal film in semiconductor layer 30 or semiconductor layer 80 in first region 11 may be 60% or less. In an area ratio in plan view, a ratio of a portion covered by the metal film in semiconductor layer 30 or semiconductor layer 80 in first region 11 may be 50% or less, and may be 40% or less.

As described above, also in the third embodiment, the ratio of the metal film covering semiconductor layer 30 or semiconductor layer 80 is lower in first region 11 than in second region 12.

The other configurations of the third embodiment are the same as those of the second embodiment. The third embodiment can also provide the same effect as that of the second embodiment. Since the ratio of the portion covered with the metal film in semiconductor layer 30 or semiconductor layer 80 in first region 11 is 60% or less, the light radiated to the outside of mesa 31 is easily radiated to the outside before being emitted from optical semiconductor element 1. Further, since first pad region 310 having a large dimension in the direction parallel to the [01-1] direction is provided, connection of a bonding wire and contact of a probe can be easily performed. In particular, when second electrode pad 300 is located at 40% or more of first region 11 in area ratio in plan view, the connection of the bonding wire and the contact of the probe can be performed particularly easily.

### Fourth Embodiment

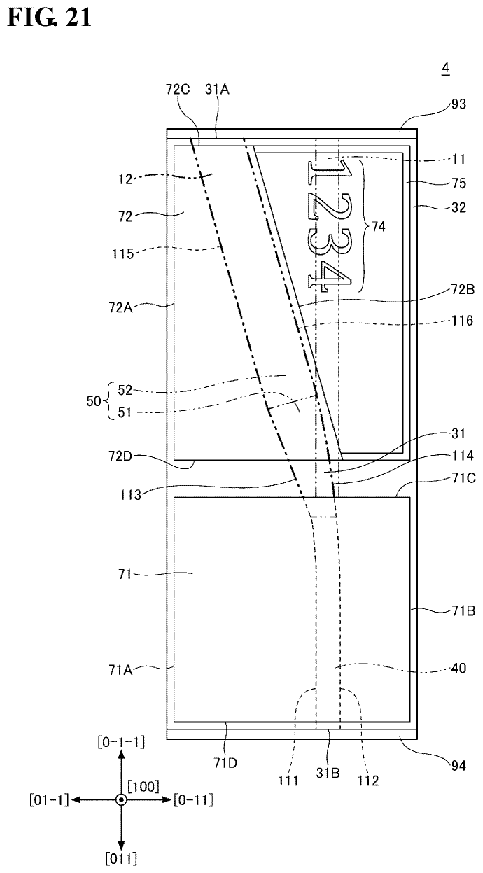

A fourth embodiment will be described. The fourth embodiment is different from the second embodiment mainly in the configuration of the metal film on semiconductor layer 80. FIG. 21 is a plan view showing an optical semiconductor element according to a fourth embodiment. In FIG. 21, p-type block layer 81, n-type block layer 82, p-type semiconductor layer 83, contact layer 84, and insulating film 90 are omitted.

As shown in FIG. 21, an optical semiconductor element 4 according to the fourth embodiment has a frame portion 75 provided on insulating film 90. Frame portion 75 includes a metal, and has, for example, an Au film. For example, frame portion 75 is made of the same material as that of second electrode pad 72. A portion of frame portion 75 may be in a portion of first region 11. Frame portion 75 is connected to the intersection of side 72C and side 72B and the intersection of side 72D and side 72B of second electrode pad 72 in plan view, and is disposed along the end portion on the [0-1-1] side and the end portion on the [0-11] side of semiconductor layer 30. Identification mark 74 is surrounded by second electrode pad 72 and frame portion 75. For example, frame portion 75 may be in a range of 10% or less of first region 11 in area ratio in plan view. As in the first embodiment, the ratio of the metal film covering semiconductor layer 30 or semiconductor layer 80 is lower in first region 11 than in second region 12. The metal included in frame portion 75 is an example of a fourth metal.

The other configurations of the fourth embodiment are the same as those of the second embodiment. The fourth embodiment can also provide the same effect as that of the second embodiment. Further, since frame portion 75 is provided, high rigidity is obtained, and deformation during conveyance using a suction collet or the like can be reduced.

### Fifth Embodiment

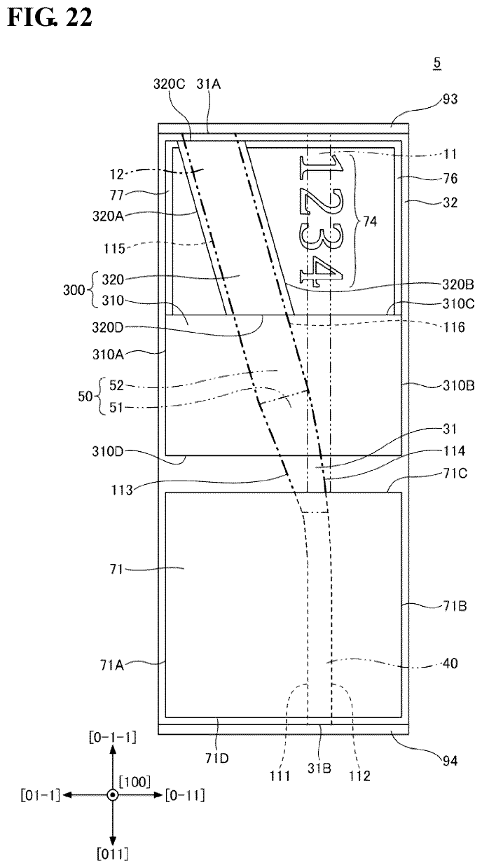

A fifth embodiment will be described. The fifth embodiment is different from the third embodiment mainly in the configuration of the metal film on semiconductor layer 80. FIG. 22 is a plan view showing an optical semiconductor element according to the fifth embodiment. In FIG. 22, p-type block layer 81, n-type block layer 82, p-type semiconductor layer 83, contact layer 84, and insulating film 90 are omitted.

As shown in FIG. 22, an optical semiconductor element 5 according to the fifth embodiment has frame portions 76 and 77 provided on insulating film 90. Frame portions 76 and 77 include metal, and have, for example, an Au film. For example, frame portions 76 and 77 are made of the same material as that of second electrode pad 72. A portion of frame portion 76 may be in a portion of first region 11. Frame portion 76 is connected to the intersection of side 310C and side 310B and the intersection of side 320B and side 320C of second electrode pad 72 in plan view, and is disposed along the end portion on the [0-1-1] side and the end portion on the [0-11] side of semiconductor layer 30. Identification mark 74 is surrounded by second electrode pad 72 and frame portion 76. For example, frame portion 76 may be in a range of 10% or less of first region 11 in area ratio in plan view. Frame portion 77 is connected to the intersection of side 310C and side 310A and the intersection of side 320A and side 320C of second electrode pad 72 in plan view, and is disposed along the end portion on the [0-1-1] side and the end portion on the [0-1] side of semiconductor layer 30. As in the first embodiment, the ratio of the metal film covering semiconductor layer 30 or semiconductor layer 80 is lower in first region 11 than in second region 12. The metal included in frame portion 76 is another example of the fourth metal.

The other configurations of the fifth embodiment are the same as those of the third embodiment. The fifth embodiment can also provide the same effect as that of the third embodiment. Further, since frame portions 76 and 77 are provided, high rigidity can be obtained, and deformation during conveyance using a suction collet or the like can be reduced.

Although the embodiments have been described in detail, the present disclosure is not limited to the specific embodiments, and various modifications and changes can be made within the scope described in the claims.

What is claimed is:

1. An optical semiconductor element comprising:
a substrate having a first main surface whose plane orientation is {100} and a second main surface provided opposite to the first main surface; and
a first semiconductor layer provided on the first main surface and provided with a mesa,
wherein the mesa includes a laser portion and an optical amplifier portion,
wherein the laser portion includes
a first surface perpendicular to the first main surface, and
a second surface perpendicular to the first main surface and parallel to the first surface,
wherein the optical amplifier portion includes
a third surface perpendicular to the first main surface and contiguous with the first surface,
a fourth surface perpendicular to the first main surface and contiguous with the second surface,
a fifth surface perpendicular to the first main surface and contiguous with the third surface,
a sixth surface perpendicular to the first main surface, contiguous with the fourth surface, and parallel to the fifth surface, and
an end surface perpendicular to the first main surface, contiguous with the fifth surface and the sixth surface, and from which light is emitted,
wherein a first distance between the first surface and the second surface is smaller than a second distance between the fifth surface and the sixth surface,
wherein the first surface and the second surface are parallel to a {01-1} plane of the substrate,
wherein the end surface is perpendicular to the {01-1} plane,
wherein the third surface and the fourth surface are inclined in a same direction with respect to each other from the {01-1} plane in a plane parallel to the first main surface,
wherein the third surface is inclined more from the {01-1} plane than the fourth surface in the plane parallel to the first main surface,
wherein the fifth surface and the sixth surface are inclined in a same direction as the third surface and the fourth surface from the {01-1} plane in the plane parallel to the first main surface,
wherein the optical semiconductor element comprises
a second semiconductor layer contacting the first surface, the second surface, the third surface, the fourth surface, the fifth surface, and the sixth surface,
a first electrode pad provided at a position where the laser portion is interposed between the substrate and the first electrode pad, including a first metal, and electrically connected to the laser portion,
a second electrode pad provided at a position where the optical amplifier portion is interposed between the substrate and the second electrode pad, including a second metal, and electrically connected to the optical amplifier portion, and
a third electrode pad provided at the second main surface, electrically connected to the substrate, and including a third metal,
wherein, in plan view, on an outer side of the first electrode pad, the optical semiconductor element comprises
a first region situated on an extension line of the laser portion on a propagation direction side of light propagating in a straight line inside the laser portion, and
a second region overlapping the optical amplifier portion, and
wherein a ratio of a metal film covering the first semiconductor layer or the second semiconductor layer is lower inside the first region than inside the second region.

2. The optical semiconductor element according to claim 1,
wherein a ratio of the first semiconductor layer or the second semiconductor layer covered by the metal film in the first region is 60% or less in terms of an area ratio.

3. The optical semiconductor element according to claim 2,
wherein a ratio of the first semiconductor layer or the second semiconductor layer covered by the second electrode pad in the first region is 40% to 60% in terms of an area ratio.

4. The optical semiconductor element according to claim 1,
wherein a ratio of the first semiconductor layer or the second semiconductor layer covered by the metal film in the first region is 20% or less in terms of an area ratio.

5. The optical semiconductor element according to claim 1, comprising:
a frame portion connected to the second electrode pad, including a fourth metal, and provided along an end portion of the first semiconductor layer in plan view.

6. The optical semiconductor element according to claim 1, comprising:
an identification mark provided apart from the second electrode pad so as to be visually confirmable and including a fifth metal.

7. The optical semiconductor element according to claim 1,
wherein the substrate is an indium phosphide substrate.
